(19) United States
(12) Patent Application Publication
(10) Pub. No.: US 2002/0153103 A1
(43) Pub. Date: Oct. 24, 2002

(54) Plasma treatment apparatus

(75) Inventor: John E. Madocks, Tucson, AZ (US)

Correspondence Address: Brinks Hofer Gilson & Lione, P.O. Box 10395, Chicago, IL, 60610, US

(73) Assignee: Applied Process Technologies, Inc.

(21) Appl. No.: 10/036,067

(22) Filed: Oct. 19, 2001

Related U.S. Application Data
(60) Provisional application No. 60/285,203, filed on Apr. 20, 2001.

(51) Int. Cl. C23F 1/00; C23C 16/00

(52) U.S. Cl. 156/345.46; 118/723 E; 118/723 MR

(57) ABSTRACT

Magnetically enhanced glow discharge devices are disclosed for the purpose of PECVD, etching or treating a substrate in a vacuum chamber. Two cathode surfaces are separated by a gap. A mirror magnetic field emanates from the cathode surfaces and passes through the gap. An anode structure forms diverging electric fields from each cathode to the anode, where the electric fields pass through the magnetic field 360 degrees around the dipole magnetic field. A closed loop electron trap is formed by the diverging electric fields and the expanding magnetic field in the gap. With a chamber pressure in the range of 0.1 to 100 mTorr and an applied voltage between the cathode and anode surfaces, a plasma is formed in the electron trap and in the plane of the trap. By shaping the plasma poles and exposing the sides of the cathode surfaces to the substrate, the created Hall current of the plasma can be brought into direct contact with the substrate.

### CROSS REFERENCE TO RELATED APPLICATION

The present patent application claims the benefit of the filing date of U.S. provisional patent application Serial No. 60/285,203, filed Apr. 20, 2001, the entirety of which is hereby incorporated by reference.

### BACKGROUND

This invention relates to magnetically enhanced plasma glow discharge systems for the purpose of coating, etching or otherwise modifying a substrate in a vacuum chamber. Many types of glow discharge devices have been devised and used. A number of these use some form of magnetic field to enhance performance. In the sections below, magnetic enhancement is reviewed for both sputtering devices and for apparatus involving non-sputtering applications.

Magnetic Confinement for Sputtering Devices

The bulk of prior art related to sputtering devices using magnetic confinement falls into two related confinement regimes: Planar magnetron sputtering confinement and axial confinement similar to a cylindrical magnetron. In planar magnetron sputtering, a magnetic field arches over a surface and forms a racetrack loop electron trap over the cathode surface. This arrangement produces the characteristic ‘race track’ glow pattern on the target. In axial confinement, the magnetic field is parallel to a cylindrical cathode surface along the length of the cylinder. In this regime, the electrons move around the cathode surface and the electron trap covers the entire cathode surface (although end losses diminish the trap effectiveness to some extent).

Magnetic Confinement in Non-Sputtering Applications

Several applications exist where sputtering is not the principal purpose of the process. These include plasma enhanced chemical vapor deposition (PECVD), plasma etching and plasma treatment. Various means to accomplish these processes are in use today, and these fields are growing rapidly. Several prior art disclosures document the benefits of magnetic enhancement. A summary of advantages gained with magnetic enhancement in a non-sputtering application would include:

Magnetic fields can make more efficient use of electrons, thereby reducing the required plasma voltage. For instance, using conducting films and DC power, diode plasmas operate upwards from 1000V while magnetically confined plasmas typically operate at 300V-800V. Lower voltages have many benefits including a reduction in particle energies critical to some processes.

Magnetic confinement of the plasma to a specific region eliminates unwanted glow around the chamber. This is particularly important in PECVD processes. Without confinement, glow and therefore deposition are more difficult to prevent in unwanted places, and this creates maintenance and operational difficulties. This is especially true for RF plasmas.

Deposition rates can be greater with magnetically enhanced plasmas. Magnetic enhancement produces a significant density increase of active species in the plasma. If the location of the plasma can be made optimal, large deposition rate improvements are possible.

The required process pressure can be significantly reduced. Without magnetic enhancement, a higher chamber gas pressure is needed to sustain a glow discharge. Typical pressures for a DC plasma are in the range of 20 mTorr to 1 Torr. With magnetic enhancement, the efficient capture and use of electrons allows chamber pressures to drop to 10 mTorr or below. Lower pressure equates to a longer free mean paths, higher particle energies and more controllable particle impingement angles as well as other factors critical to some processes.

Plasma uniformity is improved. DC or RF glow discharge suffers from plasma impedance and pressure fluctuations causing glow non-uniformities. For large scale coating or treating, this presents a serious process hurdle. Magnetic enhancement can produce stable, uniform plasmas that can be dimensionally scaled to produce films that meet tight uniformity requirements. The example of the closed loop magnetic confinement seen in magnetron sputtering sources is pertinent. The never ending containment loop on the cathode surface produces a uniform plasma which can be extended for several meters with uniformities better than 5% across the substrate.

Many prior-art, non-sputtering applications have used magnetron sputtering electron containment traps to attempt to receive the benefits of magnetic enhancement. Others recognize the benefits of magnetic enhancement but fail to achieve a closed-loop electron trap. (A true electron trap example is that of a planar magnetron racetrack.)

The present invention offers a true closed-loop electron trap for sputtering and non-sputtering applications. Many process benefits will be evident to one skilled in the art upon an understanding of the inventive system.

### SUMMARY

A novel magnetic and electric field confinement arrangement is disclosed that traps electrons in a racetrack orbit between two cathode surfaces. This novel apparatus has many uses and produces dramatic results not resembling known prior art.

The devices described below include at least two cathodes with a gap between the cathodes. A set of magnets generates a magnetic field extending between the cathodes across the gap. At least one anode structure is positioned to create an electric field extending from the cathodes to the anode structure, with at least a portion of the electric fields crossing the magnetic field to form a closed loop electron containment region within the magnetic field. With a chamber gas pressure between 0.1 mTorr and 100 mTorr and a sufficient applied voltage between the cathodes and anode, a ring of plasma is formed in the containment region. At least one substrate is positioned against the plasma outside of the gap between the cathodes to receive coating or treatment, and the plasma serves to assist a CVD process or an etch process, or otherwise to plasma treat the substrate.

Various ones of the plasma treatment devices described below include one or more of the following advantageous features:

A first exposed cathode surface is provided that is non-parallel to a second exposed cathode surface on the opposed cathode, and a magnetic field that crosses the gap passes through this first exposed cathode surface with a maximum field strength of at least 100 Gauss. This arrangement can be used to expand the plasma out away from the cathodes towards the substrate, thereby reducing the risk that the cathode surfaces may inadvertently contact the substrate, reducing heating of the substrate, and bringing more central, denser plasma into contact with the substrate. The cathode surfaces may be non-planar, asymmetrical, and/or relatively thin to improve operation of the device. The ends of the cathode surfaces may be beveled to improve operation of the electron containment region, and the cathode surfaces may be shaped to produce a strong gradient field in the gap.

The cathodes may be arranged to create an asymmetrical magnetic field across the gap, as for example to project the magnetic field out toward the substrate on one side while minimizing the space required on the opposite side of the gap.

The set of magnets can be provided with a ferromagnetic return path to enhance the magnetic field across the gap.

An enclosure may be provided around one side of the gap, and a source of process gas may be included within the enclosure. With this arrangement a substantial portion of the process gas passes through the plasma as it leaves the enclosure, thereby efficiently using the process gas.

The new plasma treatment devices described below open doors to many new plasma applications. While several devices are depicted in the attached figures, many variations employing the inventive method will be evident to one skilled in the art.

### BRIEF DESCRIPTION OF THE DRAWINGS

FIG. 1 shows an end view of a first plasma treatment device.

FIG. 2 shows an isometric view of the FIG. 1 device.

FIG. 3 shows an isometric view of the FIG. 1 device applied to a flexible web application.

FIG. 4 shows an isometric view of the FIG. 1 device applied to a rigid substrate application.

FIG. 5 shows a cross-sectional view of a second plasma treatment device.

FIG. 6 shows an isometric front side view of the device of FIG. 5.

FIG. 7 shows an isometric back side view of the device of FIG. 5.

FIG. 8 shows an isometric view of the device of FIG. 5 applied to a flexible web application.

FIG. 9 shows a cross sectional view of a third plasma treatment device.

FIG. 10 shows a schematic side view of a cathode pole of the device of FIG. 9, showing the travel of one electron.

FIG. 11 shows a cross-sectional view of a fourth plasma treatment device.

FIG. 12 shows a top view of the device of FIG. 11.

FIG. 13 shows a cross-sectional view of a fifth plasma treatment device that includes a single permanent magnet and a permeable anode inside a cathode structure.

FIG. 14 shows a cross-sectional view of a sixth plasma treatment device with cathode, anode and magnetic field elements that are asymmetrical about a plane perpendicular to the magnetic field in the gap.

FIG. 15 shows a cross-sectional view of a seventh plasma treatment device for plasma treating or coating flexible web substrates.

FIGS. 16-19 show cross sectional views of other plasma treatment devices.

FIG. 20 shows an isometric view of another plasma treatment device.

FIGS. 21-30 show cross sectional views of alternative cathode designs.

FIG. 31 shows a top view of another alternative cathode design.

### DETAILED DESCRIPTION OF THE DRAWINGS

First Preferred Embodiment

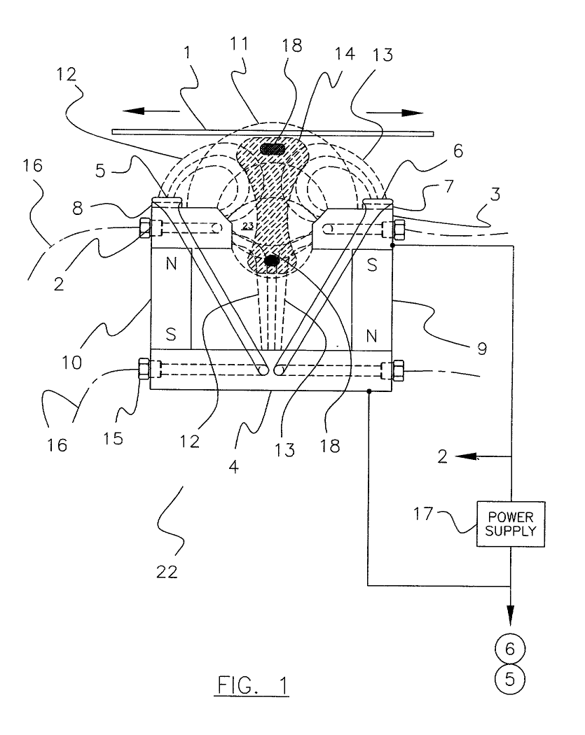

FIG. 1 shows an end view of a plasma treatment device 22 positioned adjacent to a substrate 1. The device 22 includes a magnet shunt 4, permanent magnets 9 and 10, and magnetic poles 2 and 3. These parts generate a magnetic field 11 in the gap 23 between the pole pieces 2 and 3. The device 22 includes an electrical circuit made up of (1) an anode structure comprised of the magnet shunt 4 and tubular members 5 and 6, and (2) cathodes comprised of pole pieces 2 and 3. Insulators 7 and 8 separate the pole pieces 2 and 3 from the tubular members 5 and 6. Water cooling is provided by fittings 15 and tubes 16.

When a power supply 17 is turned on, a plasma 14 lights between the poles 2, 3 and blooms out beyond the surfaces of the poles 2, 3 facing the substrate 1. The plasma 14 forms in this region because as electrons at the poles 2 and 3 attempt to escape the negative electrical potential, the electrons are initially able to move away from the poles 2 and 3, because the electric fields 12 and 13 are parallel with the magnetic field 11. Farther away from the cathode surfaces of the poles 2, 3 the electric fields 12, 13 begin to cross the magnetic fields 11, and the electrons become trapped in these crossing fields. This is shown as an electron containment ring 18 in FIGS. 1-4.

As the electrons spin in this ring 18, a Hall current into and out of the plane of FIG. 1 is created. This Hall current is contained by continuously maintaining the electric fields 12 and 13 completely around magnetic field 11. This results in Hall current containment in a closed loop within the magnetic field 11. As power is increased to the device 22 from the power supply 17, the plasma fills in between the ring 18 and creates a bright plasma 14. The substrate 1 can be conveyed to make contact with the plasma 14.

It is important that the substrate 1 not interrupt the electron containment ring 18 to the extent that the ring is broken. This can be done by experimentation. The device 22 can be moved closer to the substrate 1 to achieve the desired plasma treating, etching or other plasma effect. If the electron containment ring 18 is broken or forced into an awkward path, the plasma will clearly indicate this by distorting or following the new path. While attention must be paid to this, Hall currents can be readily pushed around allowing the substrate 1 to directly contact the Hall current.

This design represents only one possible configuration. It is important to note that several factors can be changed without affecting the basic function.

The anode tubular members 5 and 6 are not required for operation. Due to the great mobility of electrons, containing electric fields 12 and 13 can be created by the chamber walls and magnetic shunt 4 serving as the anodes.

The magnetic field 11 need not be distended to one side. This is done to give more space between the source and the substrate. A symmetrical magnetic field 11 can also be used.

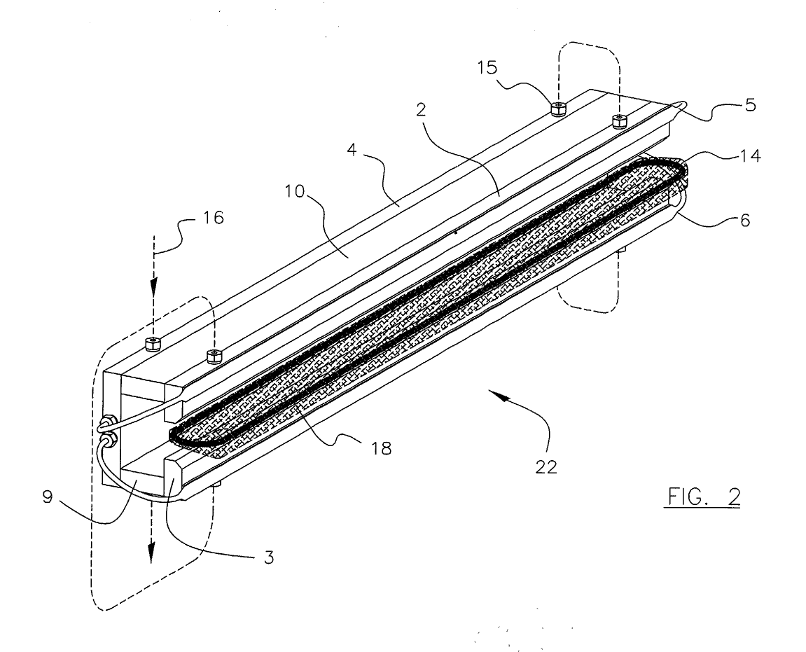

FIG. 2 shows an isometric view of the device 22 depicted in FIG. 1. This view clearly shows the plasma 14 between the poles 2 and 3 and the electron containment ring 18. The containment of Hall currents in the ring 18 without the use of a racetrack shaped magnetic field provides advantages. In this view, the Hall current turnarounds at the ends of pole pieces 2 and 3 can be seen. These turnarounds are contained within the magnetic field between pole pieces 2 and 3. As described above, this is accomplished by circumventing magnetic field 11 with electric fields 12 and 13 (FIG. 1). The result is an endless Hall current loop contained within a simple dipole magnet arrangement. Where prior-art magnetically confined plasmas such as planar magnetrons or closed drift ion sources create and contain Hall currents in a parallel plane to the substrate, the device 22 described above confines the Hall currents in a ring oriented perpendicular (±45°) to the substrate. This arrangement has many uses and provides advantages described in the following sections.

Note that while a racetrack magnetic field shape is not needed, the device 22 can be configured as a racetrack if desired. To explain further, the creation of an endless Hall current containment loop within a simple dipole magnetic field creates a magnetically enhanced plasma source that can take on a variety of shapes. For instance, a plasma source can be made with a 90 degree bend in it. It can be thought of as a line of plasma that can be bent or twisted into any desired shape. This represents an advantage over prior-art magnetically enhanced sources requiring a racetrack magnetic field.

Note also that the electron spin is in the plane normal to the magnetic field 11. The term ‘plasma grinder’ is used to convey the experience of the substrate 1 subjected to the electron spin and Hall currents circulating around loop 18.

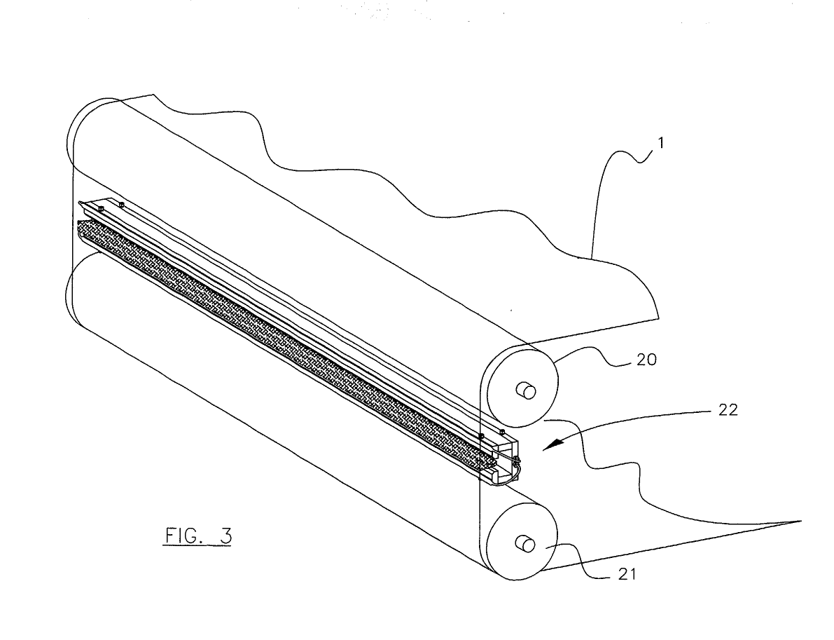

FIG. 3 shows the device 22 of FIG. 1 adapted to a web application. The substrate 1 is a flexible web is supported by rolls 20 and 21. This view shows how the device can be readily adapted into machinery.

FIG. 4 shows the device 22 of FIG. 1 adapted to a rigid planar substrate 1. Note that due to the simple nature of the device, it can be adapted to other shapes besides the planar shape that is shown in the drawings. For instance, the source can be shaped into a bow to plasma treat non-planar substrates.

Second Preferred Embodiment

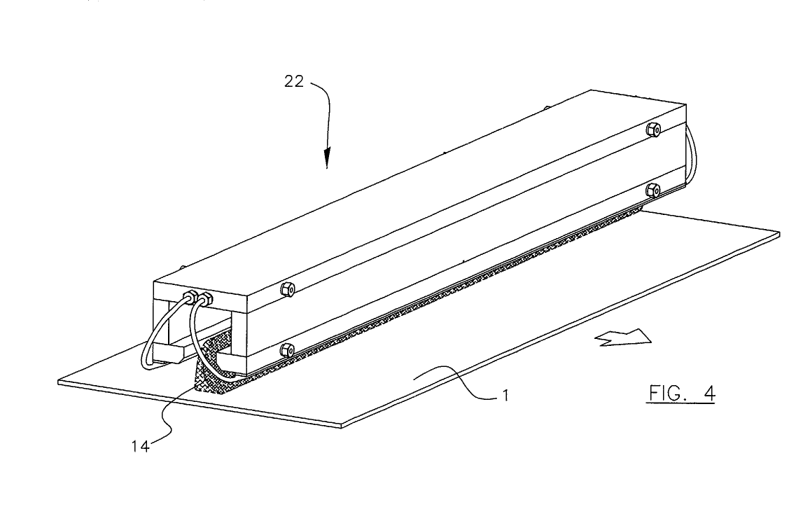

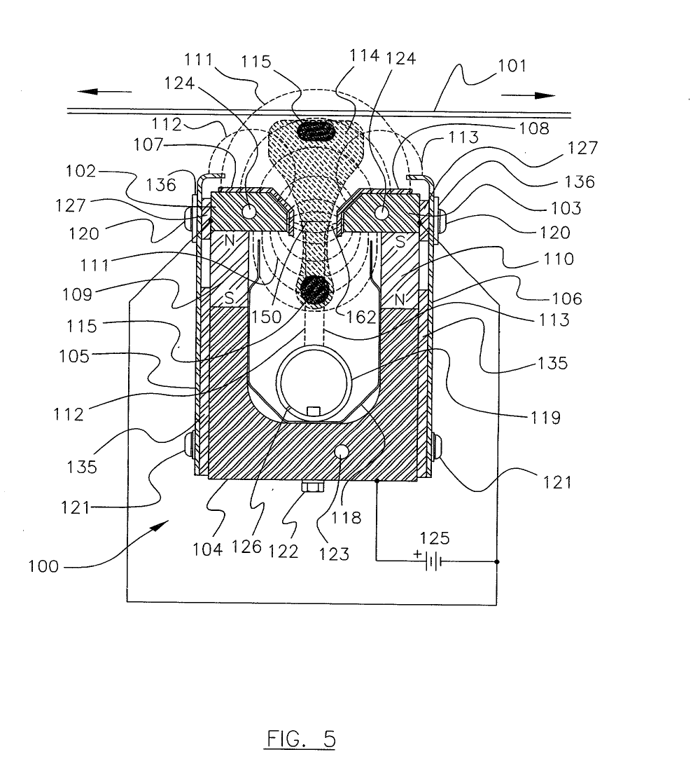

Turning now to FIGS. 5-8, these figures relate to a second plasma treatment device 100 that is arranged to treat a substrate 101 in a plasma treatment process. The plasma treatment process may vary widely depending on the application, but may include, for example, chemical vapor deposition processes, surface modification processes such as surface cleaning, etching processes, and sputter coating processes. As best shown in FIG. 5, the device 100 includes permanent magnets 109, 110 that are positioned between magnetic poles 102, 103 and a shunt 104. In this example the magnetic poles 102, 103 and the shunt 104 are formed of ferromagnetic material, and the magnets 109, 110 cooperate with the magnetic poles 102, 103 and the shunt 104 to form a magnetic circuit. The gap 162 is the largest non-ferromagnetic opening in the magnetic circuit. These parts generate an asymmetric magnetic field 111 in the gap 162 between the magnetic poles 102, 103. As shown in FIG. 5, this magnetic field 111 extends outwardly away from the magnetic poles 102, 103 to a greater extent on a side of the gap 162 facing the substrate 101 than on the opposite side of the gap 162.

Though not required, in this example the magnetic poles 102, 103 are covered by respective shells or covers 107, 108. These shells 107, 108 are preferably constructed from a material that is appropriate for the application. For example, when the device 100 is used with a titanium process, titanium can be used for the shells 107, 108. In this way any materials sputtered from the shells 107, 108 assist the deposition process or are at least benign to the deposition process. Alternatively, the shells 107, 108 can be eliminated and the magnetic poles 102, 103 may be formed of an appropriate material. As yet another alternative, the magnetic poles 102, 103 may be eliminated, and the shells 107, 108 may be applied directly to the magnets 109, 110.

The device 100 also includes an electrical circuit that includes an anode structure made up of the shunt 104 and side plates 105, 106. The electrical circuit also includes cathodes including the magnetic poles 102, 103 and the corresponding shells 107, 108. The side plates 105, 106 are secured to the shunt 104 by fasteners 121 and conductive spacer plates 135. A power source 125 applies a voltage differential between the anode structure 104, 105, 106 and the cathodes 102, 103, 107, 108. This electrical circuit creates electric fields 112, 113 extending from the covers 107, 108 to the anode structure 104, 105, 106.

In this example fasteners such as bolts 120 fasten the covers 107, 108 to the magnetic poles 102, 103. The anode plates 105, 106 hold the magnetic poles 102, 103 in place on the magnets 109, 110. Insulators 127, 136 isolate the magnetic poles 102, 103 and the bolts 120 from the anode plates 105, 106. An internal shield 118 prevents sputter material from the poles 102, 103 or the covers 107, 108 from coating the magnets 109, 110 and thereby creating an electrical short circuit between the poles 102, 103 and the shunt 104.

In this example, the magnets 109, 110 are permanent magnets formed of insulating ceramic material. Cooling is provided to both the poles 102, 103 and the shunt 104 by water which passes through these members in channels 124, 123, respectively.

Process gas is distributed in the device 100 by a tube 119 having distribution openings 126. The diameter of the tube 119 and the size and spacing of the distribution openings 126 are selected to produce uniform gas outflow across the width of the device 100. Bolts 122 fasten the tube 119 and the shield 118 to the shunt 104.

When the power supply 125 creates an adequate voltage differential between the cathodes and the anode structure, a plasma 114 lights between the shells 107, 108. A plasma is formed in this region because electrons near the shells 107, 108 attempt to escape the negative electrical potential. These electrons are initially able to move away from the shells 107, 108, because the electric fields 112, 113 are initially parallel with the magnetic field 111. At a greater distance away from the shells 107, 108, the electric fields 112, 113 begin to cross the magnetic field 111, and the electrons become trapped in these crossing fields. As the electrons spin in the region 115, a Hall current into and out of the plane of FIG. 5 is created. Outside the plane of FIG. 5, as the electric fields 111, 113 wrap around at the end of the magnetic poles 102, 103 and the covers 107, 108, the Hall current curves around and forms a continuous containment loop. At low powers, a plasma ring is clearly visible in the electron containment region 115. As the voltage supplied by the power supply 125 is increased, the plasma fills in the space between the outer edges of the electron containment region 115 and creates a bright plasma 114.

The device 100 of FIG. 5 provides an asymmetrical magnetic field, and it uses non-planar, substrate-facing exposed cathode surfaces. In particular, the magnetic field 111 is a mirror-type magnetic field at least in the peripheral portions of the electron containment region 115, and the magnetic field 111 is asymmetrical about the central magnetic field axis 150 that extends between the covers 107, 108 in the region of maximum magnetic field strength. While an asymmetric magnetic field is not necessary for Hall current containment, such a field is advantageous in that it pushes the plasma out towards the substrate 101 while pulling the plasma in on the opposite side of the gap. This field arrangement allows the substrate 101 to be positioned at a reasonable distance from the device 100, while maintaining the substrate 101 in contact with the plasma in the plasma containment region 115. The asymmetrical field increases the number of magnetic field lines emanating from the exposed cathode surfaces facing the substrate 101. Besides extending the plasma towards the substrate, this arrangement also extends the plasma over the cathode surface facing the substrate. This can be advantageous for sputtering applications.

Cathode magnetic poles 102, 103 and covers 107, 108 have a substantial portion of their surface facing the substrate 101. They are also non-planar and asymmetrical in shape with respect to the magnetic field axis 150. By facing a portion of the exposed surface of the cathodes towards the substrate 101 and allowing the magnetic field 111 that crosses the gap 162, to emanate from that exposed surface (at a maximum magnetic field strength of at least 100 Gauss), the plasma 114 is made to bloom out away from the gap 162 and toward the substrate 101. As described below, many cathode shapes and many magnetic field arrangements can be used to achieve these advantages.

As shown in FIG. 5, the substrate 101 is positioned to contact the plasma 114 and the electron containment region 115. The result is an intense bombardment of the substrate 101. This configuration is well-suited for efficient plasma treatment or plasma cleaning of the substrate surface. In other applications, by adjusting the position of the anode plates 105, 106 and/or the shape of the cathode parts 102, 103, 107, 108, by shaping the magnetic field 111, and by properly selecting the spacing between the device 100 and the substrate 101, the level of bombardment to which the substrate 101 is subjected can be adjusted from intense to minimal.

As before, it is important that the substrate 101 not interrupt the Hall current electron containment region 115 to the extent that the region 115 is broken. This can be achieved by routine experimentation. The device 100 can be moved closer to the substrate 101 to achieve the desired plasma treating, etching or other plasma effect. If the electron containment region 115 is broken or forced into an awkward path, the plasma will clearly indicate this by distorting or following the new path. Another indication of a blocked or broken Hall current electron containment region is that the plasma will be difficult to light and will require a higher voltage to operate. If desired, the Hall currents of the plasma containment region 115 can be squeezed against the substrate 101 to provide direct contact between the Hall current in the region 115 and the substrate 101.

The device 100 of FIG. 5 can be modified in many ways, including the following:

Due to the great mobility of electrons, the anode structure can take a variety of forms. In FIG. 5 the shunt 104 produces containing electric fields 112, 113 that circumvent the magnetic field 111. Other anode configurations are possible, as long as an electric field from the cathode surface to the anode surface crosses the magnetic field peripherally around the field. This is particularly advantageous in achieving efficient lighting of the plasma. Once the plasma is lit, it creates its own electric fields that tend to maintain the plasma.

The magnetic field 111 need not be distended asymmetrically to one side of the gap. A symmetric magnetic field 111 will function well.

While a racetrack magnetic field shape is not needed, the device 100 can be configured as a racetrack if desired. The endless loop Hall current containment region described above is created by a simple dipole magnetic field, and the resulting plasma source can take on a variety of shapes. For instance, a plasma source can be made with a 90° bend in it. In effect, the device 100 produces a line of plasma that can be bent or twisted to any desired shape.

In the device 100 the electron spin is normal to the magnetic field 111. The substrate 101 is subjected to this electron spin in the Hall currents circulating around the electron containment region 115.

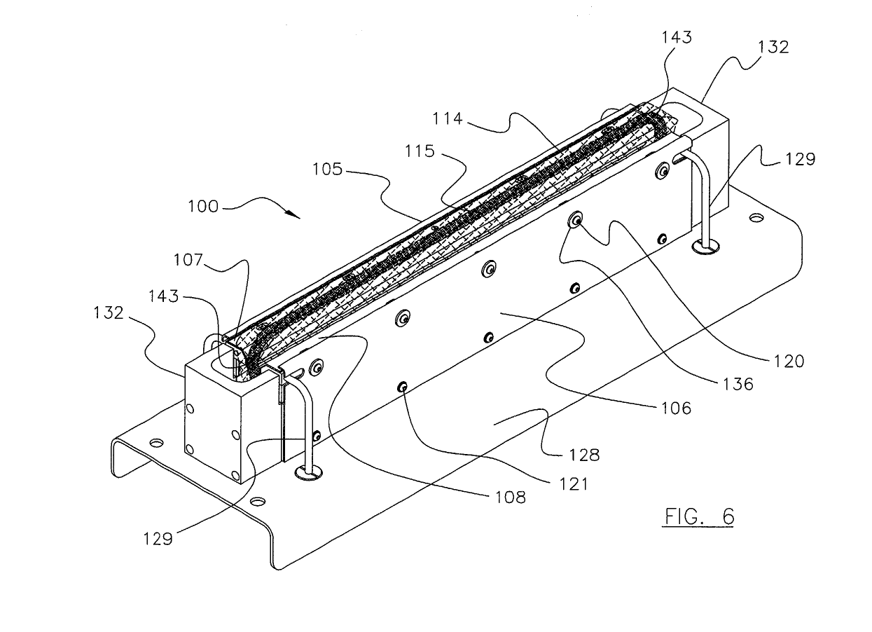

FIG. 6 shows an isometric view of the device 100. This view clearly shows the plasma 114 positioned between the covers 107, 108 and the general shape of the electron containment region 115. Note that the Hall currents are contained in the region 115 without the use of a racetrack shaped magnetic field. In this view the turnarounds 143 at the ends of the magnetic poles can be seen. The turnarounds 143 bring Hall currents in the region 115 from inside the device 100 to the outside and from outside the device 100 to the inside, all within the dipole magnetic field 111 created between the poles 102, 103 (FIG. 5). The result is an endless Hall current loop contained within a simple dipole magnetic arrangement.

FIG. 6 also shows the manner in which the anode plates 105, 106 are secured with bolts 120, 121 and insulator washers 136. Cooling water is routed to the magnetic poles 102, 103 with tubing 129, which may for example be formed of non-magnetic stainless steel. Cooling water is passed through the magnetic poles 102, 103 and the shunt 104 via gun drilled holes in these elements. To minimize corrosion of the parts 102, 103, 104, they may be constructed of magnetic stainless steel such as Grade 416 stainless steel.

As shown in FIG. 6, the device 100 includes aluminum endcaps 132 that are part of the anode circuit and are bolted to the shunt. The endcaps 132 close off the device 100 at the ends of the gap and force process gas to exit through the plasma.

The shunt 104 and the endcaps 132 cooperate with the magnets 109, 110 to form an enclosure, and the gap between the covers 107, 108 is the main route that process gas takes as it moves away from the tube 119 (FIG. 5). By implementing a dipole magnetic field with permanent magnets 109, 110 and a shunt 104 to one side of the magnetic poles 102, 103, the resulting enclosure creates a contained volume to optimize distribution of process gas. With the endcaps 132 in place, the process gas is forced to pass through the plasma on its way to the vacuum chamber. This produces a localized zone of high pressure process gas in the plasma, allowing the device 100 to operate at a lower chamber pressure and making more efficient use of the process gas. This containment and distribution of the process gas through the plasma provides substantial advantages in operation.

FIG. 7 shows a back side view of the device 100. FIG. 3 shows that the device 100 is mounted on a structural channel member 128, and tubing 129 is terminated here for attachment to supply and return lines to cathode poles 102, 103. Insulating supports 137 separate the tubing 129, 130, 131 from the beam 128. In this example electrical connections to the magnetic poles 102, 103 (and the covers 107, 108) and to the shunt 104 are made using the tubing 129, 131. Process gas is introduced into the tube 119 via the tube 130.

FIG. 8 shows the device 100 adapted to a flexible web application. In FIG. 4 the substrate 101 is a flexible web supported by rolls 141, 142. This view shows how the device 100 can readily be adapted into machinery, and how it is well-suited for treatment of a relatively wide substrate.

Third Preferred Embodiment

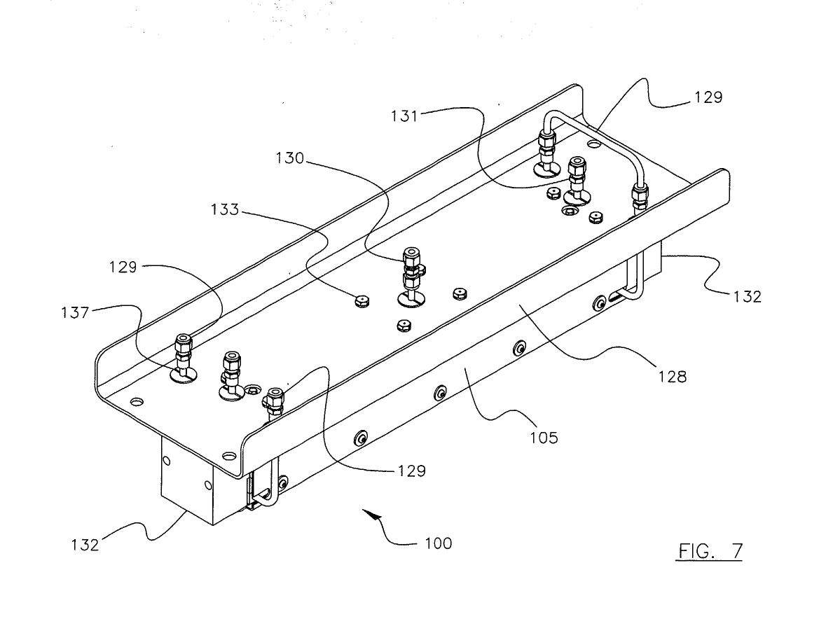

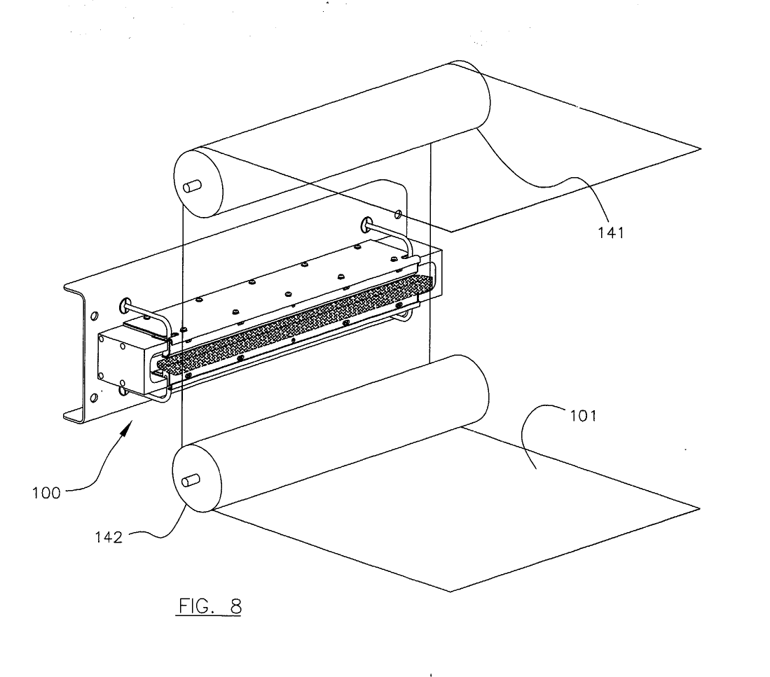

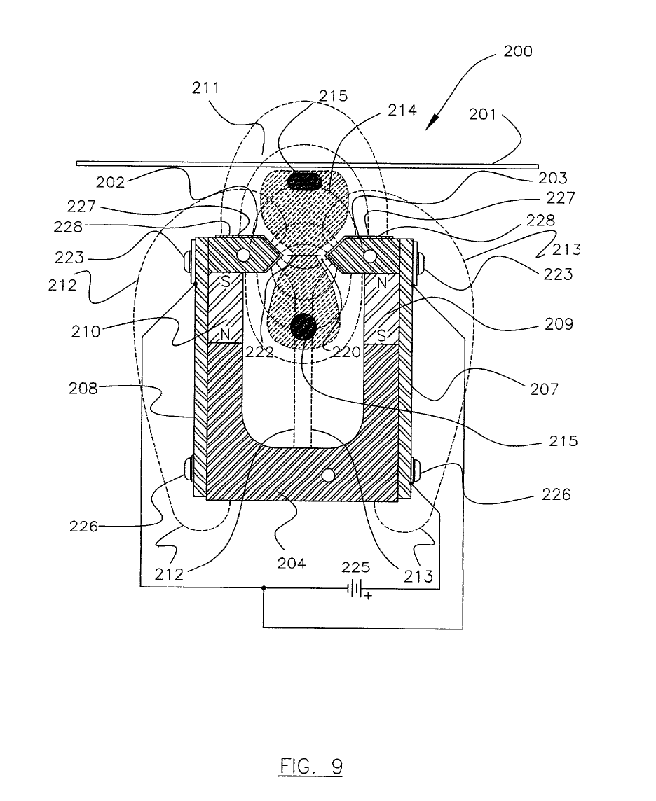

FIGS. 9 and 10 illustrate a third plasma treatment device 200. As before, the magnetic circuit is made up of magnetic poles 202, 203, the gap 220 between these poles, permanent magnets 209, 210, and magnet shunt 204. A magnetic field 211 crosses the gap 220 from one pole piece 202 to the other 203. In FIG. 9, the poles 202, 203 are held in place on the magnets 209, 210 by insulating side plates 207, 208 and fasteners 223, 226. The magnetic poles 202, 203 are covered with non-magnetic covers or shells 227. Screws 228 secure the covers 227 to the magnetic poles 202, 203. Since some sputtering of the magnetic poles 202, 203 occurs during operation, the material of the covers 227 is selected to be benign to the substrate and to the coating process. For example, titanium can be used as a cover material when oxygen is used as the process gas. This produces a clear, optically unobtrusive film on the substrate.

In this example, the poles 202, 203 act as cathodes and the shunt 204 acts as an anode, and the power supply 225 is connected to these components as shown in FIG. 9. Electric fields 212, 213 are created between the cathodes 202, 203 and the anode 204. As before, the magnets 209, 210 are insulating ceramic permanent magnets. In this configuration, the shunt 204 serves as the sole anode component. This is feasible because of the extreme mobility of electrons. Low energy electrons escaping the magnetic field and plasma readily drift to the shunt 204 from any location outside the plasma.

As before, an electron containment region 215 is formed that provides a closed loop for Hall currents when a suitable voltage is applied by the power supply 225. Although the power supply 225 is depicted as a DC power supply, an AC power supply or a pulsed DC power supply can readily be used. In fact, for dielectric PECVD coatings, an AC or pulsed power supply is preferred to allow current to pass through any insulating coating depositing on the electrodes.

In FIG. 9 the plasma 214 occupies the illustrated region.

Several useful aspects of the device 200 are illustrated in FIG. 9:

Known prior-art Penning cells or opposed target designs have taught a symmetrical magnetic field structure without a ferromagnetic return path for the magnetic field. Contrary to this, the device 200 implements a permeable material shunt 204, so that there is only one ‘air’ gap 220 in the magnetic circuit. This has several advantages: It is easier and less costly to achieve a strong magnetic field 211 in the gap 220; the magnetic field 211 tends to bloom out farther from the gap 220 without the compression effect of the return field; and less stray magnetic field exists in the vacuum chamber to cause unwanted glow. This design also recognizes that most applications are accomplished by passing the substrate 201 on one side only of the cathode gap 220. The permeable shunt 204 tends to make the magnetic field 211 in the gap asymmetrical about the magnetic field central axis. This is a benefit as the field 211 and plasma 214 tend to bloom farther out toward substrate 201 while pulling in closer to poles 202, 203 on the return path inside the device 200.

Another aspect of the device 200 is the shaping of the magnetic poles 202 and 203 to accentuate the mirror magnetic repulsion effect at the poles. In a mirror magnetic field, as a charged particle moves from the central, weaker, magnetic field to the stronger, compressed field near the poles 202, 203, the particle experiences a repulsive force. If the particle velocity toward the compressing field is large enough in relation to the particle velocity perpendicular to the magnetic field, the particle will escape through the compressed ‘end’ of the mirror field. At a lower relative speed, the particle is repelled back toward the weaker magnetic field region. The relative particle speeds, parallel and orthogonal to the magnetic field, can be related as a vector speed of angle theta. If theta is small enough, the particle will escape. This is termed the escape cone. The relative magnetic field strengths between the particle origin field and the compressed maximum field determine the angle of this cone. To maximize this effect, the difference between the minimum magnetic field strength B2 at the center of the gap 220 on the central axis 222 and the maximum magnetic field strength B1 at the cathode surface of the poles 202, 203 on the central axis 222 is made as large as possible. The ratio B1/B2 is preferably greater than 2 and more preferably greater than 4. The device 200 uses this effect, optimizing the shape of the cathode poles 202 and 203 to reduce sputtering of the poles 202, 203. In the case of FIG. 9, the poles 202, 203 are shaped into a point. This shape has an advantage over flat, parallel, facing surfaces, because it allows the compressed magnetic field lines 211 in the gap to expand. Expanding field lines drop in strength. The result is greater relative difference between the magnetic field strengths at the cathode surface of the poles 202, 203 versus the central gap area. This increases the repulsive effect on charged particles, both electrons and ions, and reduces the sputtering of poles 202, 203 for a given plasma density in the central plasma region 214. This can be seen in the plasma as a larger dark space between the cathode surfaces and the plasma 214. This mirror magnetic field repulsive effect can be implemented in other ways as will be demonstrated in later figures. To maximize the benefits of the mirror repulsive effect, pole covers 227 when used should preferably be made thin and shaped to fit snugly to the poles 202 and 203. By doing this, the strongest repulsive effect at the surfaces poles 202 and 203, can be achieved. Alternatively, the pole covers 227 may be left off to maximize the delta M field effect.

In FIG. 9, as in the other embodiments, the plasma ring 215 is a region of large electron current flow. As in magnetron sputtering, the electron current is greatest at the center of the magnetic field arch. This is due to the magnetic mirror effect, pushing the electrons toward the lowest ‘pressure’ within the magnetic field. In magnetron sputtering, the result is the characteristic racetrack etch pattern in the target. A similar effect occurs with the device 200. However, with the device 200, there is no material at the central, dense plasma region. The result is that the ion current flows into the gap 220 and through the gap 220 to the other side of the region 215. This has been termed ‘cross-feeding’ of the closed loop containment region.

FIG. 10 shows a schematic side view of the pole 202 and the magnetic field 211. The purpose of this view is to depict the path 240 of an electron 40 as it moves in the plasma. Negating collisions, the electron cannot escape the magnetic field 211 and moves in an endless cycloidal motion or orbit between poles 202, 203. Note how the magnetic field 211 extends outward from pole 202 to pole 203 (not shown) including at the ends 243, and how the electrons are continuously trapped at all points within the field. This illustrates how a true closed loop magnetic bottle can be created with a dipole magnetic field.

Fourth Preferred Embodiment

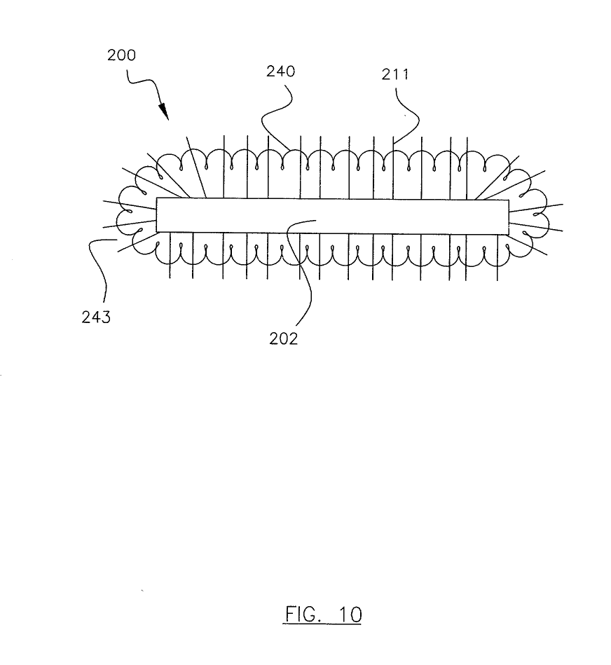

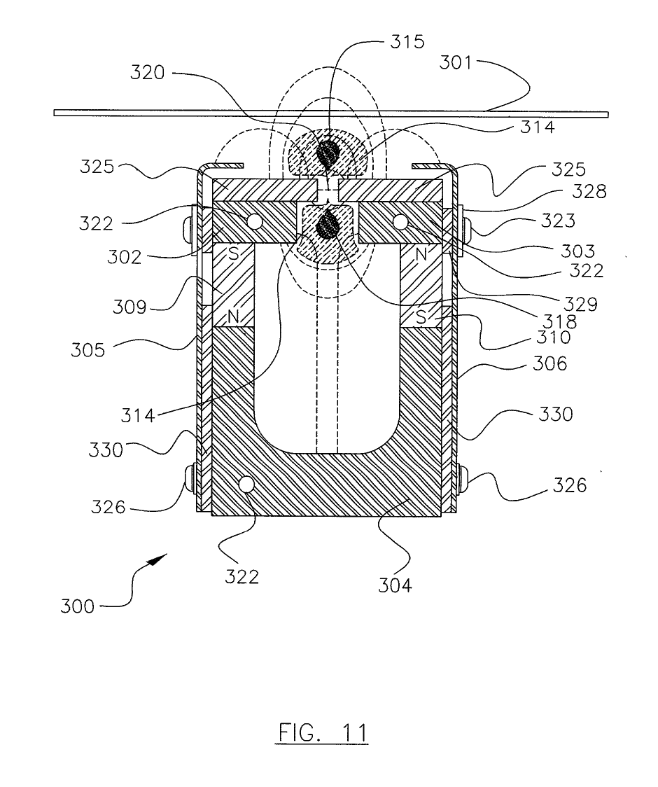

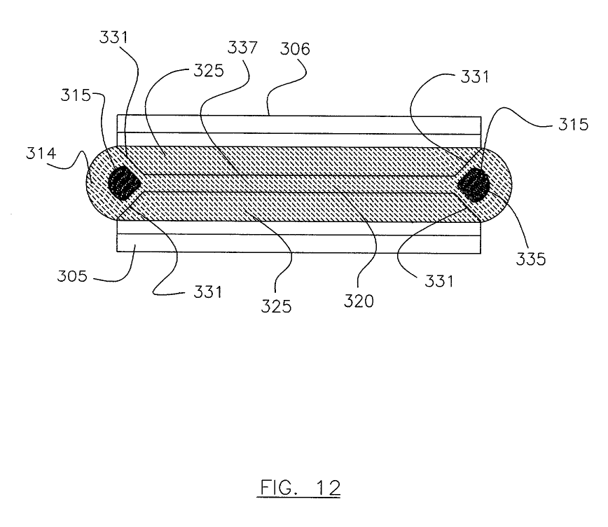

FIGS. 11 and 12 are cross-sectional and top views, respectively, of a plasma treatment device 300 that utilizes another cathode/magnetic pole configuration. In this case a substrate 301 is treated by a plasma 314 created by the device 300. The magnetic circuit includes magnetic poles 302, 304, magnets 309, 310, and a shunt 304. Cathode covers 225 are provided that care thicker than those described above and made of magnetically permeable material. The cathode covers 325 are attached to the magnetic poles 302, 303 by fasteners (not shown). The magnetic poles 302, 303 and the shunt 304 are water cooled via gun drilled holes 322. The device 300 includes an anode structure including anodes 305, 306 that are attached to the shunt 304 by spacers 330 and fasteners 326. The magnetic poles 302, 303 are held in place on the magnets 309, 310 by insulated stand offs 329, washers 328 and fasteners 323.

In this embodiment, the pole covers 325 are extended toward one another to create a narrower gap between the covers 325. This creates a stronger virtual cathode effect in the gap 320 and forces the plasma 314 out of the gap 320.

FIG. 11 also illustrates the use of anodes 305, 306 to control the shape and bloom of the plasma 314. In the device 300 of FIG. 11, the anodes 305, 306 extend inwardly toward the gap 320. Where one of the anodes 305, 306 contacts a magnetic field line, the electrons are gathered and the plasma is extinguished. By moving the anodes 305, 306 closer to the gap 320, less cathode surface with emanating magnetic field is exposed to the substrate, and the plasma bloom is reduced. In this way the placement of the anodes 305, 306 with respect to the center of the gap 320 can be controlled to vary the extend to which the plasma 314 extends outwardly from the gap 320 toward the substrate 301.

In operation, Hall current in the electron containment region 315 is almost fully outside the narrow gap 320, revolving around the outside of the gap 320. This is shown in the top view of FIG. 12. In FIG. 12, the covers 325 can be seen to be beveled at the ends. At the ends 335 of the gap 320, the plasma 314 wraps around from one side of covers 325 to the other. The optimum (lowest impedance) arrangement is when the electric field penetrates an equal strength magnetic field all around the region 315. At the ends, because of the weaker magnetic field and small gap 320, the electric field can not penetrate far enough to reach the strong magnetic field as it can in the central region 337 of the gap. To correct this, the bevels 331 are added to the covers 325. By providing the covers 325 with bevels 331, the Hall current is allowed to cross from below to above the covers 325 (and from above to below the covers 325 at the opposite end) within a region of constant magnetic field strength. This produces a lower impedance magnetic bottle. The benefits of the lower impedance plasma are lower operating voltage and lower striking voltage and/or gas pressure. The bevels 331 allow the electric field to penetrate to the stronger magnetic field and result in a consistent, tubular, plasma ring 315 extending 360 degrees around the gap. At higher powers, because of the ion penetration into the center of the plasma, the overall plasma 314 fills into the gap between the covers 325. This shifts the electric fields and reduces the need for beveled ends. The exact shape of the cathode surfaces, position of the anodes, and shape of the magnetic field are preferably optimized for each application.

The bevels 331 may be replaced with other configurations of the covers 325 or other cathodes, as long as the gap is wider at the ends 335 of the gap 320 than at the central portion 337 of the gap 320.

Fifth Preferred Embodiment

FIG. 13 shows another example of a plasma treatment device 400 in a cross-sectional view. In this configuration, a single permanent magnet 437 in the device 400 creates a magnetic field 411 in the gap 420 between poles 402, 403. Magnetically permeable bars 435 and 436 carry the field to poles 402, 403. Anode magnet shunt 432 pulls magnetic field from the space above the magnet 437 and helps to create a mirror magnetic field 411 in the gap 420 between poles 402, 403. The shunt 432 is connected and supported to anode grounded shield 439 by fasteners 434. Insulated spacers 433 isolate the bars 435 and 436 from the fasteners 434. The bars 435 and 436 are held away from non-magnetic shield 439 with insulating spacers 433 and washers 429. The cathode connections are made using washers 438 and fasteners 423 on bars 435 and 436. Pole pieces 402, 403 are screw-fastened to bars 435 and 436 (fasteners not shown). When the power supply 417 is turned on and process gas is present at a pressure between 0.1 and 100 mTorr, plasma 414 lights with Hall current in the electron containment region 418. This shows that different arrangements of cathode, anode and magnetic field components can be used to create a closed loop plasma. Once the basic concept of Hall current confinement in a dipole magnetic field between two cathode surfaces is understood, many configurations for many different applications are possible. Note that anode 432 is proximal to plasma 420, and ion propulsion due to the anode layer effect occurs in this configuration.

Sixth Preferred Embodiment

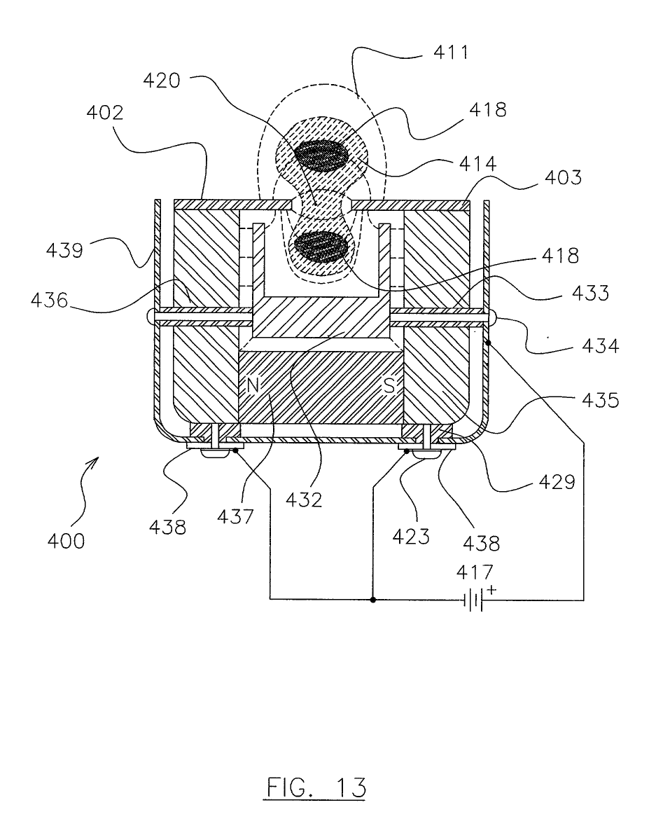

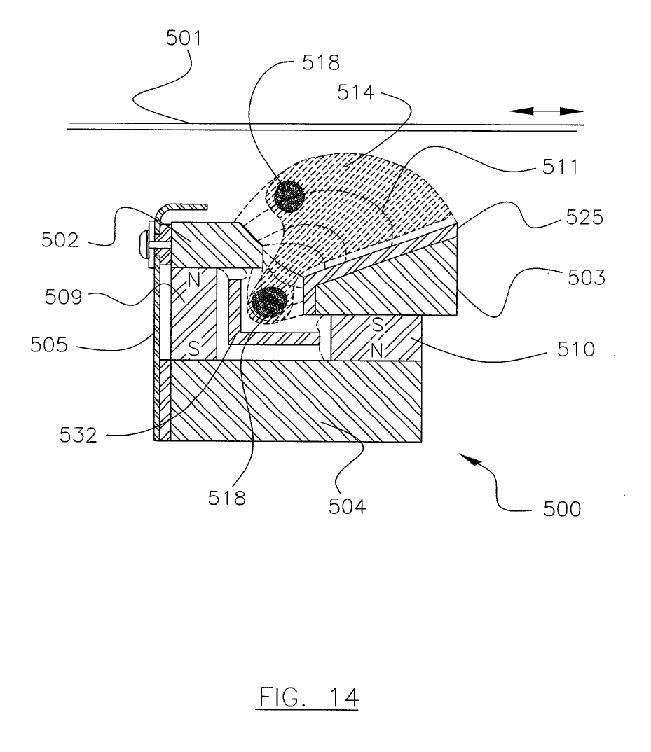

In FIG. 14, another plasma treatment device 500 is shown in a simplified, schematic form adjacent to a substrate 501. In this device, the cathode poles 502, 503, the magnets 509, 510, the magnetic field 511 and the anodes 505 and 532 are asymmetrical across the pole gap. The pole 503 has a pole cover 525, while pole 502 does not. While different than the device of FIG. 1 in many respects, this arrangement still has the fundamental configuration needed to create an endless Hall current containment-bottle: Two cathode surfaces separated by a gap, a mirror magnetic field passing through the cathode surfaces and across the gap, and sufficient anode structure to penetrate an electric field into the mirror magnetic field 360 degrees around the dipole magnetic field. When these requirements are met, many different geometries will operate to form the same characteristic low impedance, high density plasma.

The specific arrangement in FIG. 14 accentuates the sputtering of pole cover 525 on pole 503 over pole 502. This is due to the reduced mirror repulsion effect at pole 503 versus pole 502 caused by the differences in pole size and shape. Increased sputtering of pole cover 525 is also due to the unsymmetrical layout of the anodes. By positioning the anode 505 to one side of the device 500, the plasma ring 518 is shifted toward this side. This is due to the electron pull toward this anode. The result is a denser plasma 514 adjacent to pole 502 and a net ion flow toward pole cover 525 on pole 503.

Seventh Preferred Embodiment

FIG. 15 depicts a double-sided plasma treatment device 600. A magnetic field 611 is formed in the gap between symmetrical cathodes and magnetic poles 602, 603. Magnets 609, 610, anode poles 605, 606, and outside return field 647 complete the magnetic circuit. Electrically, the power supply 617 is connected to cathode poles 602, 603 and to anode poles 605, 606. A flexible substrate 601 is conveyed to contact both sides of plasma 614 using rolls 643, 644 and 645. In this embodiment both sides of the Hall current ring 618 contact the substrate. The power supply 617 can be a radio-frequency, mid-frequency or pulsed-DC supply connected to cathode poles 602, 603 and anode poles 605, 606. Cathode poles 602, 603 and anode poles 605, 606 are water cooled via gun drilled holes.

Several features of the device 600 make it a superior tool for plasma treatment, PECVD or reactive ion etching. These features include:

The cathode surfaces are not parallel, facing surfaces. The purpose here is to extend the plasma out toward the substrate. This is done as described above by exposing a portion of the cathode surface to the substrate. When the magnetic field passes through these exposed cathode surfaces (as well as the facing surfaces) a blooming field is produced that extends out of the zone between the cathodes toward the substrate(s).

The cathode poles 602, 603 are shaped into a point to produce a large gradient magnetic mirror field between the two poles 602, 603. This feature takes advantage of the magnetic mirror repulsion effect on charged particles and reduces the sputtering of the poles for a given plasma density. By pointing the poles at the center, in the region of the strongest magnetic field, a large gradient mirror field is created in the region of the most intense plasma. (As the power is increased, ion flow into the center of the containment ring produces an intense plasma at the center.) Creating a gradient mirror magnetic field in this central region reduces sputtering of the poles.

The anode structure is located away from the sides of the cathode poles to allow the plasma to extend out toward the substrate.

The result is an intense, low impedance, closed drift plasma that extends out beyond the cathode facing surfaces toward the substrate: The source created is ideally suited to plasma treating, PECVD coating, or reactive ion etching a substrate.

Further Alternatives

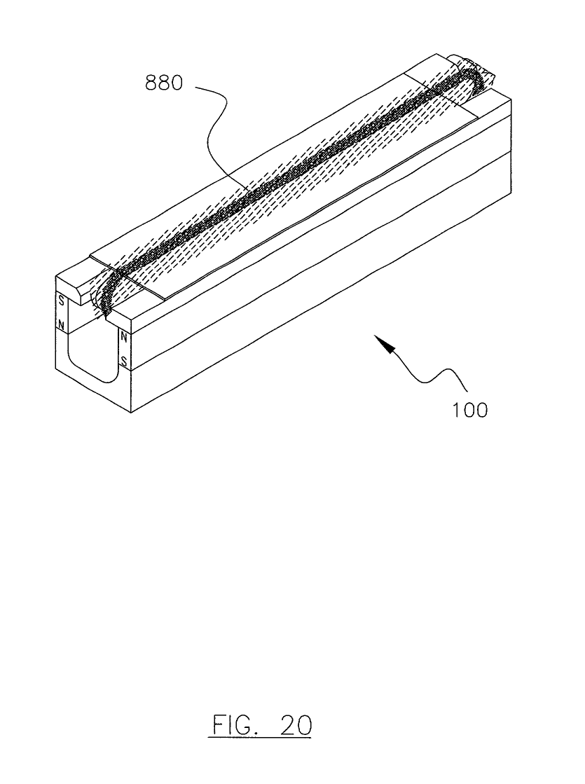

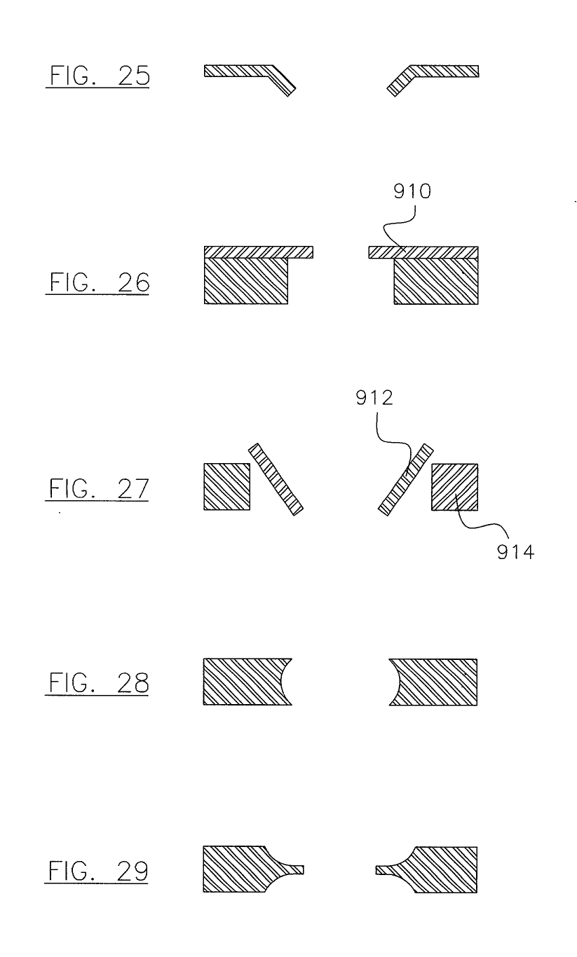

FIGS. 16 through 19 show further alternative plasma treatment devices, and FIGS. 20 through 31 show alternative magnetic pole arrangements that can be used in the plasma treatment devices described elsewhere in this specification.

The plasma treatment device 700 of FIG. 16 is in many ways similar to the device 600 of FIG. 15. The device 700 includes permanent magnets 709, 710 that are secured to cathode poles 702, 703 and to anode poles 705, 706. In this case a magnet shunt 704 is positioned in the magnetic circuit to enhance the magnetic field 711 in the gap between the cathode poles 702, 703. A substrate 701 is caused to pass adjacent to the plasma 711 on both sides of the gap between the cathode poles 702, 703. Note that in this example, the substrate 701 passes between the shunt 704 and the anode poles 705, 706, and that the gap between the cathode poles 702, 703 is not the only air gap in the magnetic circuit. Nevertheless, the magnetic shunt 704 enhances the strength of the magnetic field 711 in the gap.

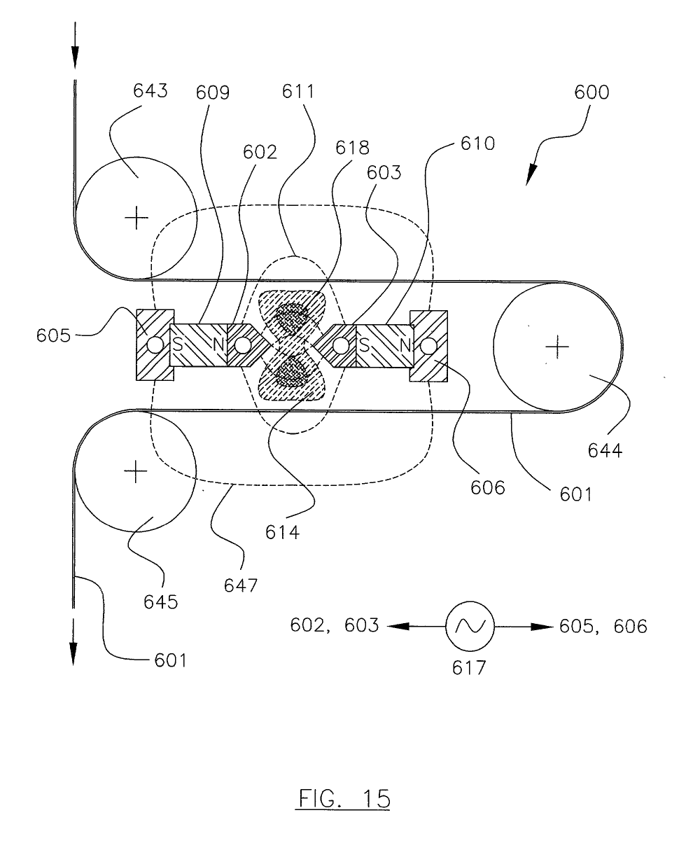

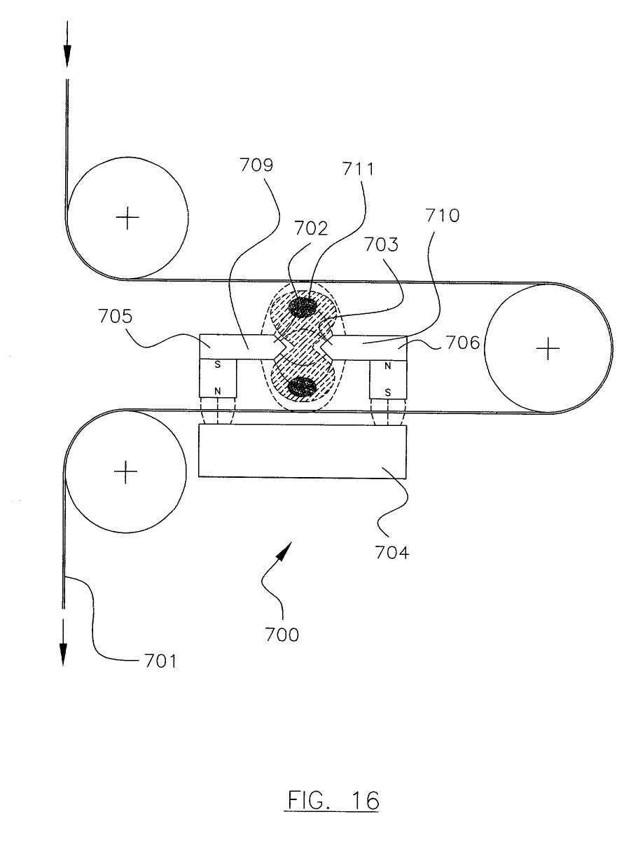

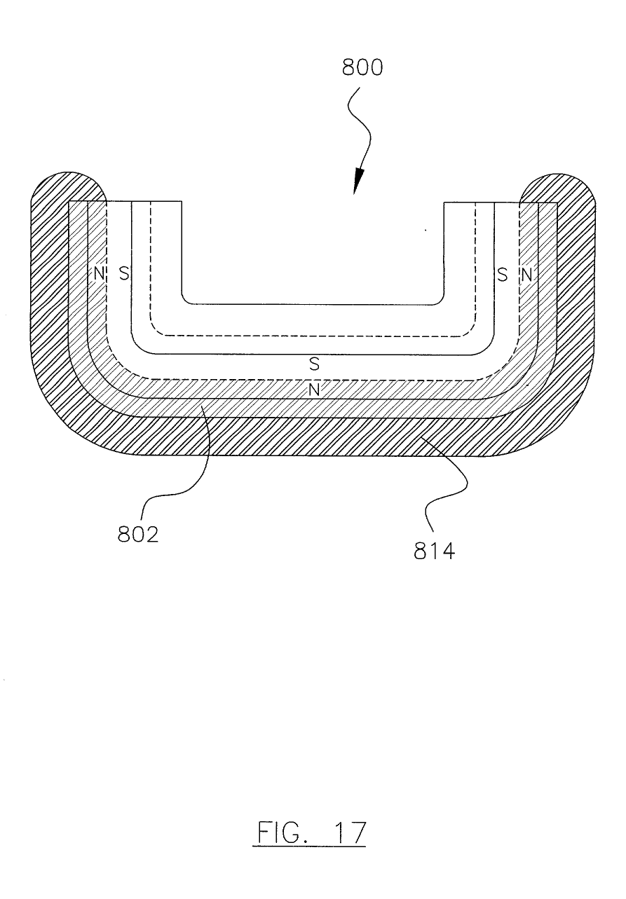

FIG. 17 shows a plasma treatment device 800 in side view. In this case the cathode 802 is not rectilinear along the length dimension, but is instead bent into a U-shape. This causes the plasma 814 to be generated in a U-shape. The device 800 is well suited for the treatment of concave substrates. Of course, many other shapes are possible for plasma treatment devices of the type described above, and in general the line of plasma 814 can be configured almost as desired in both the lateral plane (the plane passing across the gap between the cathodes in the region of strongest magnetic field) and in the elevation plane (transverse to the lateral plane).

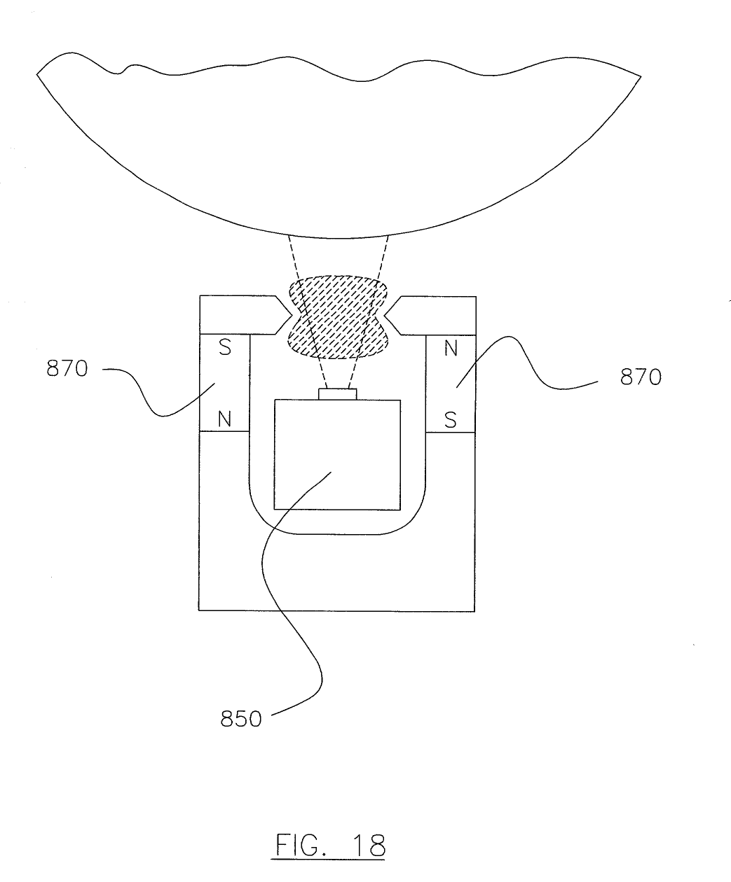

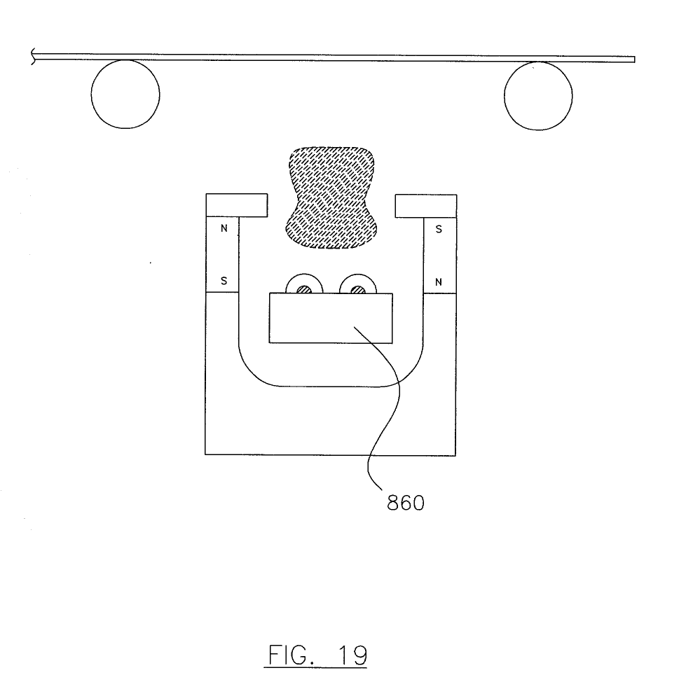

FIGS. 18 and 19 are similar in that both show a plasma treatment device that may be substantially identical to the device 100 described above. The cathode poles can be shaped in accordance with any of the examples provided this specification. An important difference between the devices of FIGS. 18 and 19 and that of FIG. 5 is that the source of process gas is shown as a evaporation source 850 (FIG. 18) and as a magnetron sputter source 860 (FIG. 19). As an example of a evaporation source, the source 850 may be an activated reactive evaporation source, known to those skilled in the art as an ARE source. As an example, the magnetron sputter source 860 may be operated in the metal mode by distributing argon gas inside the enclosure. Outside the enclosure, oxygen may be distributed to react with the metal in the plasma and on the substrate. These embodiments again provide the advantage that the process gas generated by the sources 850, 860 is contained within an enclosure such that it must pass through the plasma in the gap as it exits the plasma treatment device. If desired, the magnets 870 may be implemented as electromagnets. Similarly, all of the other examples of this specification may substitute electromagnets for the illustrated permanent magnets.

FIG. 20 shows another variant of the device 100 described above. In this case the cathode poles have been shaped somewhat differently and a non-magnetic target material 880 has been positioned on the substrate side of the gap adjacent the cathode poles. Both sides of the target material 880 are sputtered during operation.

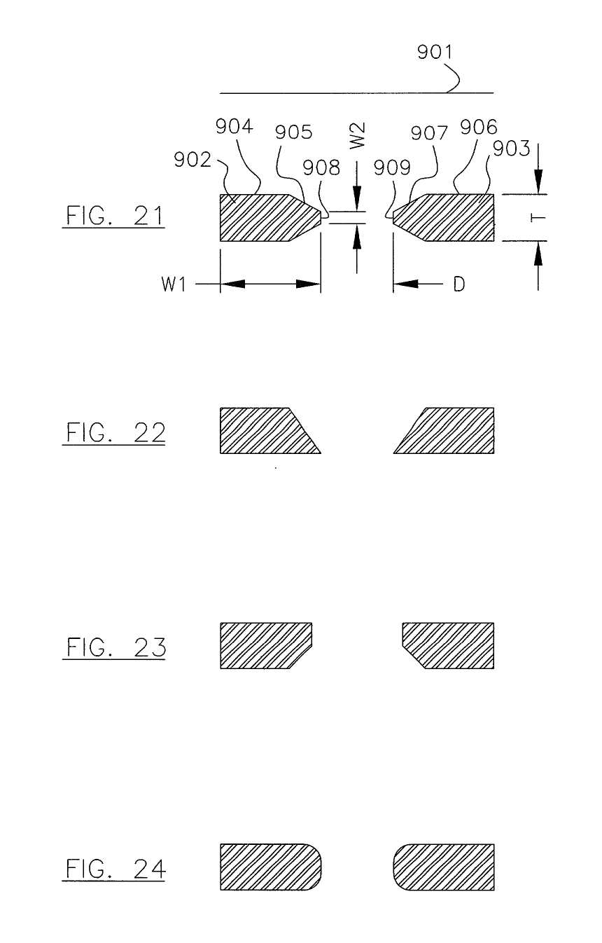

FIGS. 21 through 31 illustrate various alternative cathode designs that may be used in any of the embodiments discussed above. FIGS. 21 though 30 are taken in the plane of FIG. 5, and show only the cathodes and the gap. The remaining elements of the plasma treatment device are not shown, but can be constructed as described above. FIG. 21 shows cathodes 902, 903 positioned adjacent to a substrate 901. The cathodes 902, 903 include first exposed surfaces 904, 905, 906, 907 that face the substrate 901. The cathodes 902, 903 also include second exposed cathode surfaces 908, 909 that are parallel to one another and that face one another across the gap. The first exposed surfaces 904, 905 are non-parallel to the second exposed surface 909. Preferably, the combined width of the first exposed surfaces 904, 905 (measured parallel to the dimension D) is greater than or equal to 1 cm. This width is indicated by the reference symbol W1. The width W2 of the second exposed surface 909 is substantially less than the width W1. In general, the ratio W1/W2 is preferably greater than 0.2 and more preferably greater than 1. In many applications the length of the cathodes (measured perpendicularly to the plane of FIG. 21) will be greater than W2 or W1.

The thickness T of the cathodes can, for example, be less than 80 mm, more preferably between 3 and 25 mm and most preferably between 10 and 13 mm. The minimum cross-sectional dimension D of the gap can, for example, be in the range of 1 to 150 mm, more preferably 12 to 25 mm, and most preferably 18 to 20 mm. Though the magnetic circuit is not shown in FIG. 21, the surfaces 904, 905, 906, 907, 908, 909 are exposed surfaces in the sense that strong magnetic fields emanate from these surfaces and cross the gap from one cathode to the other. The emanating magnetic fields from all of these surfaces that cross the gap have a maximum magnetic field strength of at least 100 Gauss. Thus, as used herein, an exposed cathode surface may be oriented either to face the opposing cathode or to face the substrate. As used herein, a surface is said to face the substrate if it is positioned such that a line normal to the surface passes through the substrate.

FIGS. 22 through 29 show other cathode shapes that can be used. In all cases, the cathodes (which function as magnetic poles) can be provided with covers as described above, though such covers are not shown in FIGS. 21 through 29. FIG. 22 shows cathodes with beveled surfaces and FIG. 24 shows cathodes with rounded surfaces. FIG. 26 shows cathodes with stepped or ridged surfaces. In FIG. 26 the element 910 may be formed of magnetic or non-magnetic material. In FIG. 27, the element 912 is preferably formed of non-magnetic material, while the cathode 914 is formed of magnetic material. FIG. 30 shows an arrangement in which an insulating cover 916 is positioned on each cathode, only in a central region of the cathode.

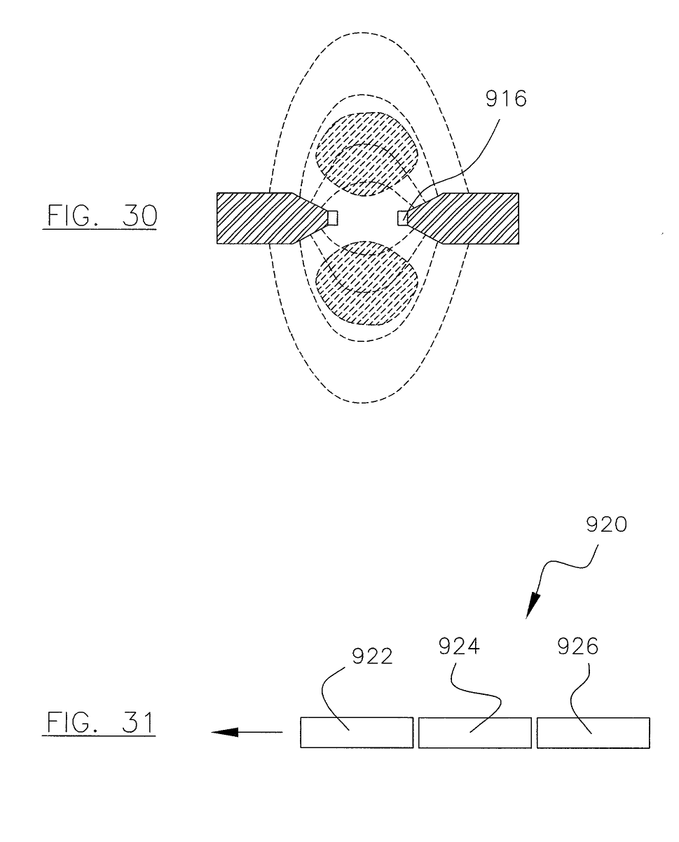

FIG. 31 differs from FIGS. 21 through 30 in that it shows a top view of a segmented cathode 920 that is made up of multiple segments 922, 924, 926 that are positioned adjacent to one another along the axial direction that extends parallel to the long dimension of the gap. The use of such segmented cathodes may facilitate construction and design in some application.

Concluding Remarks

The embodiments illustrated in the drawings use a novel magnetic and electric field confinement arrangement that traps electrons in a racetrack orbit perpendicular (±45°) to the substrate surface and that allows the substrate to contact the Hall current directly. This arrangement produces important advantages. Benefits and features of these embodiments can include the following (depending on the application):

A high efficiency plasma is created in an expanded region between and beyond two cathodes surfaces. At voltages between 300-600 volts, currents as low as 5 mA produce a stable, bright glow for a 150 mm long plasma. This is possible because electrons are contained beyond the dark space in a closed loop race track. The ions produced by collisions in this racetrack do not ‘see’ the cathode surface, and a relatively dense plasma is formed per watt of power.

The magnetic and electric field confinement geometry produces an endless racetrack confinement zone similar to a planar magnetron sputtering device with a simplified magnetic pole structure. Unlike magnetron sputtering, the devices described above produce this confinement racetrack perpendicular to the substrate relatively distant from the cathode surface. The simplified magnetic pole requirements open up new and improved plasma source designs. The drawings show several possible arrangements. Many more will be evident to one skilled in the art.

Similar to magnetron sputtering, the efficient plasma confinement allows operation at low pressures and voltages. Many process advantages are gained by this: Plasma does not light in other parts of the chamber or on electrode surfaces outside of the containment zone; the plasma is characteristically stable and uniform; lower plasma voltage requirements make the power supplies safer and less costly; ion and electron energy levels are more uniform and easier to control.

Though an intense plasma appears adjacent to the substrate, the low power supply current flow relative to plasma density results in lower substrate, cathode and anode temperatures. Several significant advantages are gained by low temperature operation of plasma processes, and the cost and complexity of water cooling may in some cases be simplified or eliminated. Also, temperature sensitive substrate materials may be treated, and long dwell times in the plasma can be tolerated.

The plasma containment method can be arranged to minimize sputtering of the electrodes. This is due to both the orientation of the electric and magnetic fields at the cathode surface and the mirror magnetic field repulsion effect. With this arrangement, electrons are not trapped near the cathode surface. Where electron confinement does occur in the center of the gap, fewer of the ions that are created reach the cathode surface, and therefore there is less sputtering of the cathode surface. Plasma treating or reactive etching then is accomplished with less sputtering coating contamination, and the heat associated with sputtering is reduced.

The substrate can be introduced into direct contact with the plasma without electrically biasing or making the substrate an anode or cathode. Not only is this easier to implement, but the energies received by the substrate are generally reduced down to the floating potential. This is a significant benefit to processes such as RIE or PECVD, where high ion energies can damage substrate processing structures or cause excessive crosslinking. Alternatively, the substrate can be biased to adjust the particle impingement rates and energies. Substrate biasing is a known and common technique for this purpose.

Plasma uniformity across wide substrates is excellent, and the plasma sources described above have an extendable confinement arrangement. Uniformity of plasma density across wide substrates is an important advantage.

The plasma is formed in a region that extends away from the gap toward the substrate. This reduces the risk of the substrate inadvertently contacting the structure of the device, and it makes it possible to bring more central, denser plasma into contact with the substrate. This can allow for faster treatment, PECVD deposition, and/or etch rate. As substrates become larger and the plasma treatment device extends over a length of 1 m or greater, and increased separation between the substrate and the device is very beneficial in accommodating substrate conveyance inaccuracies, substrate handling problems (e.g., overlapping substrates), and device installation tolerances.

Non planar cathode surfaces aid in shaping the magnetic field to position the plasma farther away from the cathode surfaces toward the substrate. Also, non-planar cathode surfaces tend to produce a stronger gradient mirror magnetic field across the cathodes. This results in a stronger mirror magnetic repulsion effect at the poles, and reduces ion impingement of the poles for a given plasma density.

The relatively thin cathodes described above (measured transversely to the plane of the substrate) also help shape the magnetic field to push the field out toward the substrate. Thinner cathode poles also tend to create a larger gradient mirror magnetic field between the cathode surfaces. As discussed above, this provides an advantage in focusing the plasma into the central region of the gap and reducing sputtering of the poles. Thin poles also enhance ion flow through the gap from one side to the other of the electron containment ring, thereby cross-feeding the Hall current drift on the two sides of the ring.

The asymmetric magnetic field geometries described above assist in projecting the magnetic field out toward the substrate on one side of the gap, while minimizing the space required for the plasma treatment device on the other side. Such asymmetrical magnetic fields allow the substrate to be moved farther from the plasma treatment device, thereby reducing radiative heating of the substrate, easing installation concerns, and allowing the electric field to penetrate between the substrate and the cathodes to reach the gap area.

The use of a ferromagnetic return path in the magnetic circuit makes it easier to achieve a strong magnetic field across the gap. This is because the air gaps in the magnetic circuit are reduced, and the result is a lower cost, easier to use plasma treatment device. In many cases, ceramic magnets can be used instead of rare earth magnets. Also, the use of a magnet shunt tends to assist in forming the magnetic field in the gap so that is blooms farther out towards the substrate. The shunt also facilities control of stray magnetic fields and reduces the possibility of unwanted plasma glow within the vacuum chamber.

The distribution of process gas via an enclosure that causes the process gas to pass through the plasma allows the plasma treatment device to operate a lower chamber pressures (in the region of 0.1 mTorr) without putting a large pumping load on the vacuum chamber. Also, the amount of process gas that is used can often be reduced. Because most or all of the process gas that is distributed passes through the plasma, very efficient use of a reactive process gas such as oxygen can be made. By minimizing the reactive gas load, the isolation of the reactive gas is made easier and less costly. It also allows the plasma treatment device to be positioned closely adjacent to another process. It is also cost efficient to use the least amount of process gas.

Many other alternatives are possible. For example, the pole pieces described above are not required in all applications, and the magnetic fields from the magnets can be used to create the desired dipole field without the pole pieces. In this case, water-cooled non-magnetic bars (e.g., formed of titanium) can be used to take up the volume of the pole pieces and covers described above. The pole pieces are advantageous in that they make it easier to shape the magnetic field, they allow water cooling to be hard plumbed to the pole pieces, and they allow the covers to be changed without breaking water seals in a low cost, efficient manner.

As used herein, the term “set” is intended broadly to encompass one or more. Thus, a set of magnets can include 1, 2, 3 or more magnets.

The term “region” is intended broadly to encompass both ring-shaped regions and disc-shaped regions.

The term “enclosure” is intended broadly to encompass a structure that substantially prevents large volumes of process gas from exiting other than via the plasma. Thus, an enclosure does not have to be completely sealed. As described above, an enclosure can be formed partly or entirely from elements included in the magnetic circuit, including the magnets and shunts described above.

The term “facing” is intended broadly to encompass both parallel and angled relationships. Thus, a first surface is said to face a substrate whether the first surface is parallel to the substrate or angled to the substrate at an angle less than 90°.

The terms “electron containment region” and “electron containment ring” indicate that high energy electrons are substantially contained in the region or ring by crossing magnetic and electric fields. Those skilled in the art will recognize that low energy electrons are generally not contained by such containment regions or rings.

The foregoing detailed description has discussed only a few of the many forms that this invention can take. For this reason, this detailed description is intended by way of illustration and not by way of limitation. It is only the following claims, including all equivalents, that are intended to define the scope of this invention.

1. A plasma treatment apparatus comprising:
at least first and second cathodes separated by a gap, said first cathode comprising a first exposed cathode surface, said second cathode comprising a second exposed cathode surface, and said first exposed cathode surface oriented non-parallel to said second exposed cathode surface;
a set of magnets operative to generate a magnetic field exiting from one of the cathodes and entering the other of the cathodes, thereby crossing the gap;
said magnetic field comprising a first magnetic field portion crossing the gap and passing through said first exposed cathode surface, said first magnetic field portion comprising magnetic field lines having a maximum field strength of at least 100 Gauss;
at least one anode structure positioned to create an electric field extending from the cathodes to the anode structure, at least a portion of said electric field crossing said magnetic field and forming a closed-loop electron containment region within said magnetic field, a sufficient voltage between the anode structure and the cathodes operative to form a plasma within the magnetic field when a gas is present near the containment region at a gas pressure between 0.1 and 100 mTorr; and
at least one substrate positioned to be treated by said plasma.

2. The apparatus of claim 1 wherein the substrate is positioned to be treated by the plasma with a treatment selected from the group consisting of: a chemical vapor deposition process, a surface modification process, an etching process, a sputter-coating process, and combinations thereof.

3. The apparatus of claim 1 wherein the magnetic field comprises a mirror-type magnetic field at least in a peripheral portion of the magnetic field.

4. The apparatus of claim 1 wherein the first exposed cathode surface faces the substrate.

5. The apparatus of claim 4 wherein the first exposed cathode surface extends over a length measured along the gap and a width measured transverse to the length, and wherein the width is at least 1 cm.

6. The apparatus of claim 1 wherein at least one of the cathodes comprises a non-planar cathode surface.

7. The apparatus of claim 6 wherein at least one of the cathodes comprises a facing cathode surface having a shaped selected from the group consisting of:
a point, a bevel, a rounded surface, a stepped surface, a ridged surface, and combinations thereof.

8. The apparatus of claim 1 wherein the first cathode comprises a facing cathode surface oriented to face the second cathode, wherein the first exposed cathode surface has a length extending along the gap and width W1 measured transverse to the length, wherein the facing cathode surface has a width W2 measured transverse to the length, and wherein W1/W2 is no less than 0.2.

9. The apparatus of claim 8 wherein the length is greater than the width W2.

10. The apparatus of claim 8 wherein the width W1 is no less than 1 cm.

11. The apparatus of claim 1 wherein the cathodes comprise ends and a central portion, and wherein the cathodes are shaped such that the gap is wider at the ends than at the central portion.

12. The apparatus of claim 11 wherein the ends of the cathodes are beveled.

13. The apparatus of claim 1 wherein the magnetic field comprises a maximum strength magnetic field line, wherein the maximum strength magnetic field line has a maximum magnetic field strength B1 adjacent one of the cathodes and a minimum magnetic field strength B2 at a central portion of the gap, and wherein B1/B2 is greater than 2.

14. The apparatus of claim 13 wherein B1/B2 is greater than 4.

15. The apparatus of claim 1 wherein the electron containment region is centered in a plane that is oriented perpendicular (±45°) to a portion of the substrate adjacent to the gap.

16. A plasma treatment apparatus comprising:
at least two cathodes separated by a gap;
a set of magnets operative to generate a magnetic field exiting from one of the cathodes and entering the other of the cathodes, thereby crossing the gap;
at least one anode structure positioned to create an electric field extending from the cathodes to the anode structure, at least a portion of said electric field crossing said magnetic field and forming a closed-loop electron containment region within said magnetic field, a sufficient voltage between the anode structure and the cathodes operative to form a plasma within the magnetic field when a gas is present near the containment region at a gas pressure between 0.1 and 100 mTorr; and
at least one substrate positioned to be treated by said plasma;
wherein the magnetic field is asymmetrical with respect to a central axis of the gap extending between the cathodes, and wherein the electron containment region extends farther away from the central axis on one side of the gap than on the other side of the gap.

17. The apparatus of claim 16 wherein the substrate is positioned on said one side of the gap.

18. A plasma treatment apparatus comprising:
at least two cathodes separated by a gap;
a set of magnets operative to generate a magnetic field exiting from one of the cathodes and entering the other of the cathodes, thereby crossing the gap;
at least one anode structure positioned to create an electric field extending from the cathodes to the anode structure, at least a portion of said electric field crossing said magnetic field and forming a closed-loop electron containment region within said magnetic field, a sufficient voltage between the anode structure and the cathodes operative to form a plasma within the magnetic field when a gas is present near the containment region at a gas pressure between 0.1 and 100 mTorr;
at least one substrate positioned to be treated by said plasma; and
a set of ferromagnetic elements magnetically coupled to the set of magnets to provide a ferromagnetic return magnetic path, thereby enhancing the magnetic field across the gap.

19. The apparatus of claim 18 wherein the electron containment region comprises first and second portions situated on respective sides of the gap, and wherein the second portion is situated between the gap and at least one element selected from the group consisting of:
the set of magnets and the set of ferromagnetic elements.

20. The apparatus of claim 18 wherein the set of magnets and the set of ferromagnetic elements are included in a magnetic circuit, and wherein the gap is the largest non-ferromagnetic opening in the magnetic circuit.

21. A plasma treatment apparatus comprising:
at least two cathodes separated by a gap;
a set of magnets operative to generate a magnetic field exiting from one of the cathodes and entering the other of the cathodes, thereby crossing the gap;
at least one anode structure positioned to create an electric field extending from the cathodes to the anode structure, at least a portion of said electric field crossing said magnetic field and forming a closed-loop electron containment region within said magnetic field, a sufficient voltage between the anode structure and the cathodes operative to form a plasma within the magnetic field when a gas is present near the containment region at a gas pressure between 0.1 and 100 mTorr;
at least one substrate positioned to be treated by said plasma;
an enclosure extending from the cathodes around a portion of the electron containment region positioned away from the substrate; and
a source of process gas positioned within the enclosure.

22. The apparatus of claim 21 wherein a major portion of the process gas from the source passes through the plasma containment region in leaving the enclosure.

23. The apparatus of claim 21 wherein the source of process gas comprises a tube positioned within the enclosure, said tube comprising gas-release openings.

24. The apparatus of claim 21 wherein the source of process gas comprises an evaporation source.

25. The apparatus of claim 21 wherein the source of process gas comprises a sputter source.

26. The apparatus of claim 21 wherein the source is positioned between the enclosure and a portion of the electron containment region.

27. The apparatus of claims 1, 16, 18 or 21 wherein the cathodes comprise removable shells.

28. The apparatus of claims 1, 18 or 21 wherein the magnetic field is asymmetrical with respect to a central axis of the gap extending between the cathodes, and wherein the electron containment region extends farther from the central axis on a front side of the gap facing the substrate than on a back side of the gap facing away from the substrate.

29. The apparatus of claims 1, 16, 18 or 21 wherein the cathodes are asymmetrical with respect to a central axis of the gap.

30. The apparatus of claims 1, 16, 18 or 21 wherein the set of magnets comprises a permanent magnet.

31. The apparatus of claims 1, 16, 18 or 21 wherein the set of magnets comprises an electromagnet.

32. The apparatus of claims 1, 16, 18 or 21 wherein the gap is elongated along a length axis, and wherein each of the cathodes comprises a plurality of segments positioned adjacent to one another along the length axis.

33. The apparatus of claims 1 or 18 wherein the at least one substrate is positioned on both sides of the gap for treatment by the plasma.
